(19) United States
(12) Patent Application Publication
(10) Pub. No.: US 2003/0224259 A1
(43) Pub. Date: Dec. 4, 2003

(54) Method of lithographic printing from a reusable aluminum support

(75) Inventors: Eric Verschueren, Merksplas (BE); Joan Vermeersch, Deinze (BE)

Correspondence Address: LEYDIG VOIT & MAYER, LTD, TWO PRUDENTIAL PLAZA, SUITE 4900, 180 NORTH STETSON AVENUE, CHICAGO, IL, 60601-6780, US

(73) Assignee: AGFA-GEVAERT, Mortsel (BE)

(21) Appl. No.: 10/431,191

(22) Filed: May 7, 2003

Related U.S. Application Data
(60) Provisional application No. 60/386,292, filed on Jun. 5, 2002.

(30) Foreign Application Priority Data
May 29, 2002 (EP) 02100574.9

(51) Int. Cl. B41M 7/00; G03F 7/26

(52) U.S. Cl. 430/19; 430/300; 101/450.1; 101/465; 101/467; 101/478

(57) ABSTRACT

A printing method is disclosed wherein a grained and anodized aluminum support is coated with an image recording layer comprising hydrophobic thermoplastic polymer particles. The heat-sensitive imaging material thus obtained is then image-wise exposed and processed, thereby obtaining a material having a lithographic image which consists of hydrophobic printing areas on a hydrophilic support and which is used as a printing master in a printing press. After the press run, the lithographic support is recycled by removing the hydrophobic printing areas from the hydrophilic surface of the aluminum support. The recycled support is then reused in a next cycle of coating, exposing, processing and printing. By using a grained and anodized aluminum support having a hydrophilic surface with a surface roughness, expressed as arithmetical mean center-line roughness Ra, which is less than 0.45 μm, the run length of the printing master is improved.

### FIELD OF THE INVENTION

The present invention relates to a lithographic printing method wherein, after a press run, the lithographic support is recycled and recoated with an image recording layer comprising hydrophobic thermoplastic polymer particles. The heat-sensitive printing plate material thus obtained is then exposed with a fresh image, processed and used as a printing master in a next press run.

### BACKGROUND OF THE INVENTION

In lithographic printing, ink and an aqueous fountain solution are supplied to the surface of a printing master that contains a lithographic image consisting of ink accepting (oleophilic) and water-accepting (hydrophilic) areas. The inked image pattern is then transferred from the surface of the master to a blanket cylinder having a compressible surface. From the blanket cylinder the image is impressed onto paper. The master is typically a printing plate that carries a lithographic image on a dimensionally stable support such as an aluminum sheet. The aluminum plate is secured to the plate cylinder of a printing press by a mechanical lock-up mechanism that defines positional registration between the plate and the surface of the cylinder. After the end of the press run, the mechanical lock-up system is released so that the printing plate can be removed and discarded and another printing plate with a fresh image can be positioned and locked into place. A new print job can then be started.

Printing masters are generally obtained by the so-called computer-to-film method wherein each color selection is transferred to graphic arts film using an image-setter. After processing, the film can be used as a contact mask for the exposure of an imaging material called plate precursor and after plate processing, a printing plate is obtained which can be used as a master. These steps are usually performed in dedicated exposure and processing equipment and the printing plates are then transported to the printing press and attached to the printing cylinder by press operators using a lock-up mechanism built into the cylinder itself. Although the attachment of the printing cylinder is generally a manual operation, robotic means have been developed for positioning and securing the printing plates.

In recent years the so-called computer-to-plate method has gained a lot of interest. This method, also called direct-to-plate method, bypasses the creation of film because the digital data are transferred directly to a plate precursor by means of a so-called plate-setter. On-press imaging is a direct-to-plate method (also called direct-to-press), wherein the image is exposed on the plate while said plate is mounted on the plate cylinder of a printing press. The major advantage of the latter method compared to off-press plate making is the improved registration between printing stations of a multi-color printing press.

Two types of such on-press imaging methods are known. According to a first type, a printing plate precursor is mounted on a printing press, image-wise exposed, optionally developed, and then used as a printing master and finally removed from the press and disposed of, thus requiring a new plate material for each image. An example of this technology is the Heidelberg Model GTO-DI, manufactured by Heidelberg Druckmaschinen AG (Germany) which is described in detail in U.S. Pat. No. 5,339,737. A drawback of this method is the need to use a new plate for each press run, thus increasing the cost of the printing process.

In a second type of on-press imaging systems, the same lithographic support is used in a plurality of press runs (hereinafter called printing cycles). In each printing cycle, a heat-sensitive or photosensitive layer is coated on the lithographic support to make a printing plate precursor and after image-wise exposure and optional development a printing master is obtained. After the press-run, the ink-accepting areas of the printing master are removed from the lithographic support in an image erasing step so that the support is recycled and can be used in a next cycle of coating, exposing and printing without the need to mount a new plate on the cylinder. Examples of such on-press coating and on-press imaging systems are described in e.g. U.S. Pat. No. 5,188,033; U.S. Pat. No. 5,713,287; EP-A 786 337 and EP-A 802 457. The latter patent application describes an apparatus comprising a printing member, means for applying a uniform image recording layer, means for scan-wise exposing said recording layer in accordance with an image pattern and means for developing said recording layer to leave an image on said printing member, the image consisting of ink-accepting areas on an ink-repellent background or ink-repellent areas on an ink-accepting background. According to a preferred embodiment, the recording layer comprises hydrophobic thermoplastic polymer particles in a hydrophilic binder.

A problem associated with the latter composition is the limited maximum run length of the printing master thereby obtained. Degradation of the print quality due to image wear limits the run length to a maximum of typically 25 000 printed copies. Also the limited mechanical robustness (scratch sensitivity) and chemical resistance towards press chemicals such as plate cleaners, blanket cleaners and fountain additives contribute to the mentioned low printing endurance. It is therefore an object of the present invention to provide a method of lithographic printing wherein the same lithographic support is used for a plurality of print jobs and wherein the image recording layer does not require a processing step with alkaline chemicals and which provides a high run length and meets the many other requirements of a lithographic printing plate material such as scratch resistance and chemical resistance.

### SUMMARY OF THE INVENTION

The method of the present invention consists of a plurality of print cycles, wherein each print cycle comprises the steps (a)-(e) which can generally be defined as follows:

(a) providing a lithographic support having a hydrophilic surface.

(b) coating: making a printing plate precursor by applying an image recording layer on the lithographic support; the plate precursor is also referred to herein as “imaging material”.

(c) exposing: image-wise exposing the image recording layer to heat or light.

(d) processing (also called developing): making a printing master having a lithographic image by removing the non-exposed areas of the image recording layer from the lithographic support.

(e) printing: supplying ink to the lithographic image and transferring the ink from the lithographic image to paper by means of a printing press.

(f) erasing the lithographic image from the lithographic support.

The image erasing step is also called herein the cleaning step. The recycled support, which is obtained after step (f), is then reused is in a next print cycle wherein the support is recoated with an image recording layer and then exposed with a fresh image, processed and used as a printing master in a next press run. The number of consecutive print cycles using the same support is at least 2, preferably more than 20 and can be higher than 50 or even higher than 100 provided that an efficient image erasing method is used which leaves no ghost image on the support and meanwhile neither deteriorates the lithographic quality of the support.

The run length improvement is realized by applying an image recording layer comprising hydrophobic thermoplastic polymer particles onto a smooth aluminum support, as defined in claim 1. The effect that a smooth aluminum support provides a higher run length for a plate working according to heat-induced coalescence of hydrophobic thermoplastic polymer particles is quite surprising: the reason why a smooth surface, characterized by an arithmetical mean center-line roughness Ra which is less than 0.45 μm, provides a significant reduction of the image wear during printing is not well understood; the skilled person would expect that a rough surface provides a better adherence to the coalesced polymer particles than a smooth surface. Nevertheless, the contrary is observed and a smooth lithographic support with Ra value as defined herein unexpectedly provide the higher run length.

The preferred methods of the present invention are capable of providing a lithographic printing master that can be used for a press run of at least 30 000, and more preferably at least 60 000 copies without visible wear of the image. The best embodiments even enable a press run of more than 100 000 copies.

Specific features for preferred embodiments of the present invention are set out in the dependent claims. Further advantages and embodiments of the present invention will become apparent from the following description.

### DETAILED DESCRIPTION OF THE INVENTION

All the steps of the method of the present invention are preferably carried out by the end user, e.g. in a print shop, instead of a plate manufacturer. The steps can be carried out on-press, i.e. while the lithographic support is mounted on a cylinder of a rotary printing press. Alternatively, one or more steps, except printing step (e), can be carried out by means of an off-press apparatus. “Off-press apparatus” as used herein defines an apparatus which is not integrated in the printing press but located nearby the printing press so that the operation of the apparatus can take place while the press is printing. E.g. the exposure step (c) can be carried out on- or off-press. On-press exposure offers the benefit of obtaining a prefect registration of the printing masters in multi-color presses immediately after exposure. The off-press exposure method on the other hand offers a shorter press-down time than the on-press exposure method because the exposure can take place while the press is printing.

In the embodiments using on-press exposure, the processing is preferably carried out by supplying ink and/or fountain (or single-fluid ink) to the exposed image recording layer. In the embodiments using off-press exposure, alternative processing methods (discussed in more detail below) can also be used or the exposed plate can be mounted on the press and then processed by supplying ink and/or fountain (or single-fluid ink).

Besides the exposure step (c) and the processing step (d), also the coating step (b) and/or the cleaning step (f) can each be carried out by means of an off-press apparatus. In such methods, the press-down time is minimal because during a given press run, the imaging material(s) of the next print job can be coated and optionally also exposed and processed with an off-press apparatus and the material(s) of the previous print job can be cleaned and recoated with an off-press cleaning apparatus while the press is printing. All the steps of cleaning, coating, exposing and processing can be carried out with a single off-press apparatus.

Cleaning and/or processing liquid can be supplied to the support using the same means as used for the coating step, e.g. a single spray or ink-jet head can be used for applying the coating solution, the cleaning liquid and/or the processing liquid. Or several steps can be carried out simultaneously by using a head which consists of different sections which each carry out one of the steps of the method of the present invention and which travel consecutively over the support, e.g. a head which comprises a nozzle for supplying a cleaning liquid and/or a nozzle for supplying the coating solution and/or a laser exposure head and/or a nozzle for supplying the processing liquid.

Transfer of plates, coated and/or exposed with an off-press apparatus, to the press and transfer of used plates from the press to a cleaning apparatus can be done manually, but, more advantageously, the off-press apparatuses are mechanically coupled to the printing press by mechanical transferring means. According to such an embodiment, the lithographic support can be coated and optionally also exposed with an off-press apparatus, subsequently mechanically transferred to the press, and after the pressrun, the used printing master can be mechanically transferred to an off-press cleaning apparatus where the coating is removed from the support, which can then be used again in a next cycle of coating, exposing, processing, printing and cleaning. The transferring means may comprise a mechanism that is capable of moving, transporting or conveying the support, the imaging material or the used printing master from one apparatus to another. Such mechanisms are known in the art and widely used in plate-handling equipment. The transferring means may comprise conveyor belts, grippers, suction caps, rollers, chains, etc. The means used for mechanically transferring a material to the printing press preferably contain a mechanism which mounts the material on the plate cylinder. The means used for mechanically transferring the used printing master from the press to the cleaning apparatus preferably contain a mechanism which removes the printing master from the plate cylinder. Plates are normally fixed to the cylinder by clamps, whereas sleeves are slid over the cylinder.

In embodiments wherein an off-press apparatus is combined with a multi-color press, it may be advantageous to use a stacking apparatus which acts as a buffer for temporary storage of a cleaned support, an imaging material or a printing master so that a single off-press apparatus can be used for cleaning, coating, exposing and/or processing all the color selections. More details and specific embodiments of various configurations wherein one or more off-press apparatuses, suitable for use in the method of the present invention, are coupled to a printing press by mechanical transferring means and a stacking apparatus are described in EP-A 1142706 and 1118473. Such systems enable a fully-automated workflow wherein the press down-time is minimal and which can be carried out without special skills.

The lithographic support

The support may be a sheet-like material or it may be a cylindrical element such as a sleeve. In the latter option, a sheet may be soldered in a cylindrical form, e.g. by means of a laser. Such cylindrical support can be slid on the print cylinder of a printing press instead of being mounted thereon such as a conventional printing plate.

The support used in the method of the present invention is a grained and anodized aluminum support having a hydrophilic surface that is characterized by a low surface roughness, expressed as arithmetical mean center-line roughness (Ra), sometimes also referred to as CLA (center-line average). Ra as used herein is defined in ISO 4287/1 (=DIN 4762) and references therein. Ra values reported herein have been measured according to ISO 4288 and references therein by a mechanical profile method using a contact stylus with a very thin tip (also optical profile methods are known; such optical methods systematically provide higher values than the ISO method). The apparatus used for measuring Ra was a Talysurf 10 from Taylor Hobson Ltd.

The Ra value of the hydrophilic surface of the grained and anodized aluminum support used in the method of the present invention is lower than 0.45 μm, preferably lower than 0.4 μm and even more preferably lower than 0.3 μm. A grained and anodized aluminum support having a hydrophilic surface characterized by the mentioned low Ra values is briefly referred to herein as a “smooth support”. The lower limit of the Ra value may be 0.05 μm, preferably 0.1 μm. Besides surface roughness, also the anodic weight of the support (g/m² of Al₂O₃ formed on the aluminum surface) affects the run length. According to the present invention, even higher run lengths can be obtained for a given roughness Ra by forming more than 2.5 g/m² of aluminum oxide at the hydrophilic surface, a value above 3.0 or even 3.5 g/m² being even more preferred.

Graining and anodizing of aluminum lithographic supports is well known. The grained aluminum support used in the method of the present invention is preferably an electrochemically grained support. The acid used for graining can be e.g. nitric acid. The acid used for graining preferably comprises hydrogen chloride. Also mixtures of acids, e.g. hydrogen chloride and acetic acid, can be used.

The relation between electrochemical graining and anodizing parameters such as electrode voltage, nature and concentration of the acid electrolyte or power consumption on the one hand and the obtained lithographic quality in terms of Ra and anodic weight on the other hand is well known. More details about the relation between various production parameters and Ra or anodic weight can be found in e.g. the article “Management of Change in the Aluminum Printing Industry” by F. R. Mayers, to be published in the ATB Metallurgie Journal. So the skilled person is well aware of the settings of the various parameters which are required for making a smooth surface on a grained aluminum support or for making a given anodic weight during aluminum anodization.

The steps of graining and anodizing are preferably not part of step (a) of the present invention because graining and anodizing are procedures using strong acids and electrodes under high voltage and therefore not suited for implementation at the end user's site such as a print shop. Instead, it is more convenient to use a grained and anodized aluminum support, supplied by a printing plate manufacturer, and have it recycled by the end user after a press run according to the present invention, using an image erasing method that removes the lithographic image from the support without significantly affecting the lithographic quality, in particular the surface roughness and the anodic weight, of the grained and anodized surface.

Optionally, the recycled grained and anodized aluminum support may be treated in a so-called refreshing step to restore the hydrophilic properties of its surface. This refreshing step can be carried out after the image erasing step and before applying an image recording layer on the support, e.g. during step (a) of the method of the present invention. The refreshing step can be similar to the so-called post-treatment step which typically follows the well known aluminum graining and anodizing methods used for making conventional lithographic printing plates. For example, the aluminum support may be silicated by treating its surface with a sodium silicate solution at elevated temperature, e.g. 95° C. Alternatively, a phosphate treatment may be applied which involves treating the aluminum oxide surface with a phosphate solution that may further contain an inorganic fluoride. Further, the aluminum oxide surface may be rinsed with an organic acid and/or salt thereof, e.g. carboxylic acids, hydroxycarboxylic acids, sulfonic acids or phosphonic acids, or their salts, e.g. succinates, phosphates, phosphonates, sulfates, and sulfonates. A citric acid or citrate solution is preferred. This treatment may be carried out at room temperature or may be carried out at a slightly elevated temperature of about 30 to 50° C. A further post-treatment involves rinsing the aluminum oxide surface with a bicarbonate solution. Still further, the aluminum oxide surface may be treated with polyvinylphosphonic acid, polyvinylmethylphosphonic acid, phosphoric acid esters of polyvinyl alcohol, polyvinylsulfonic acid, polyvinylbenzenesulfonic acid, sulfuric acid esters of polyvinyl alcohol, and acetals of polyvinyl alcohols formed by reaction with a sulfonated aliphatic aldehyde. It is further evident that one or more of these post-treatments may be carried out alone or in combination. More detailed descriptions of these treatments are given in GB-A-1 084 070, DE-A-4 423 140, DE-A-4 417 907, EP-A-659 909, EP-A-537 633, DE-A-4 001 466, EP-A-292 801, EP-A-291 760 and U.S. Pat. No. 4,458,005.

Another embodiment of a suitable refreshing step is described in EP-A 1188579. The refreshing liquid described therein is an aqueous solution having a pH<7 and comprises acidic compounds such as citric acid, polyacrylic acid or silica containing compounds that are capable of lowering the pH of water. Preferably the refreshing liquid comprises a compound according to formula I:

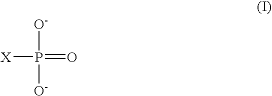

wherein X is OH, O⁻ or a polymer backbone. The counter ion can be, depending on the pH, H⁺ or a metal cation such as an alkali or alkaline earth metal or a transition metal, e.g. chromium. Suitable examples of the compound according to formula (I) are polyvinylphosphonic acid, copolymers of vinylphosphonic acid with acrylic acid and vinyl acetate, acrylamidoisobutylene phosphonic acid. Preferably the compound is phosphoric acid or a phosphate salt.

Alternatively, a compound according to formula (I) can also be added to the cleaning liquid that may be used for erasing the image during step (e) as described in EP-A 1188578. In such an embodiment, a separate refreshing step may be omitted.

The image recording layer

The image recording layer applied on the lithographic support is heat-sensitive, thereby providing a plate precursor which can be handled in normal working lighting conditions (daylight, fluorescent light) for many hours. The image-recording layer comprises a polymer latex as image forming ingredient, more particularly hydrophobic thermoplastic polymer particles which are capable of heat-induced coalescence. Specific examples of suitable hydrophobic polymers are e.g. polyethylene, poly(vinyl chloride), poly(methyl (meth)acrylate), poly(ethyl(meth)acrylate), poly(vinylidene chloride), poly(meth)acrylonitrile, poly(vinyl carbazole), polystyrene or copolymers thereof. According to preferred embodiments, the thermoplastic polymer comprises at least 50 wt. % of polystyrene, and more preferably at least 60 wt. % of polystyrene. A suitable latex consists of polystyrene and an optional stabilizer.

In order to obtain sufficient resistivity against mechanical damage and towards press chemicals, such as the hydrocarbons used in plate cleaners, the thermoplastic polymer preferably comprises at least 5 wt. %, more preferably at least 30 wt. % of nitrogen containing monomeric units or of units which correspond to monomers that are characterized by a solubility parameter larger than 20, such as (meth)acrylonitrile or monomeric units comprising sulfonamide and/or phthalimide pendant groups. Other suitable examples of such nitrogen containing monomeric units are disclosed in European Patent Application no. 01000657, filed on Nov. 23, 2001. A specific embodiment of the hydrophobic thermoplastic polymer is a homopolymer or a copolymer of (meth)acrylonitrile and/or styrene, e.g. a copolymer consisting of styrene and acrylonitrile units in a weight ratio between 1:1 and 5:1 (styrene:acrylonitrile). A 2:1 or 3:2 ratio provides excellent results.

The weight average molecular weight of the thermoplastic polymer particles may range from 5,000 to 1,000,000 g/mol. The hydrophobic particles preferably have a number average particle diameter below 200 nm, more preferably between 10 and 100 nm. The amount of hydrophobic thermoplastic polymer particles contained in the image-recording layer is preferably between 20 wt. % and 95 wt. % and more preferably between 45 wt. % and 90 wt. % and most preferably between 65 wt. % and 85 wt. %, relative to the layer as a whole.

The image-recording layer may further comprise a hydrophilic binder, e.g. homopolymers and copolymers of vinyl alcohol, acrylamide, methylol acrylamide, methylol methacrylamide, acrylic acid, methacrylic acid, hydroxyethyl acrylate, hydroxyethyl methacrylate or maleic anhydride/vinylmethylether copolymers. The hydrophilicity of the (co)polymer or (co)polymer mixture used is preferably the same as or higher than the hydrophilicity of polyvinyl acetate hydrolyzed to at least an extent of 60 percent by weight, preferably 80 percent by weight. Binders with carboxylic pendant groups, e.g. poly(meth)acrylic acid, are preferred.

The image-recording layer may also contain other ingredients such as additional binders, surfactants, colorants, development inhibitors or accelerators, and especially one or more compounds that are capable of converting infrared light into heat. The colorants are preferably dyes or pigments which provide a visible image after processing. Particularly useful light-to-heat converting compounds are for example infrared dyes, carbon black, metal carbides, borides, nitrides, carbonitrides, bronze-structured oxides, and conductive polymer dispersions such as polypyrrole, polyaniline or polythiophene dispersions. Anionic cyanine dyes are preferred.

The coating step (b)

During the coating step, the image-recording layer is applied on the hydrophilic surface of the support. For obtaining the right coating thickness, it may be necessary to repeat the coating several times on the same support. The coating may also contain one or more additional layer(s), adjacent to the image-recording layer. Such additional layer can e.g. be an adhesion-improving layer between the image-recording layer and the support; or a light-absorbing layer comprising one or more of the above compounds that are capable of converting infrared light into heat; or a covering layer which is removed during processing.

The coating can be applied by heat- or friction-induced transfer from a donor material as described in EP-A 1048458, or by powder coating, e.g. as described in EP-A 974455 and 1097811, or by coating a liquid solution according to any known coating method, e.g. spin-coating, dip coating, rod coating, blade coating, air knife coating, gravure coating, reverse roll coating, extrusion coating, slide coating and curtain coating. An overview of these coating techniques can be found in the book “Modern Coating and is Drying Technology”, Edward Cohen and Edgar B. Gutoff Editors, VCH publishers, Inc, New York, N.Y., 1992. It is also possible to apply the coating solution to the support by printing techniques, e.g. ink-jet printing, gravure printing, flexo printing, or offset printing. Ink-jet printing as described in EP-A 1179422 and especially valve-jet printing as described in unpublished EP-A no. 01000065, filed on Mar. 22, 2001, is highly preferred.

According to a most preferred embodiment, a coating solution is sprayed on the support by means of a head comprising a spray nozzle. Preferred values of the spraying parameters have been defined in EP-A 1084830 and 1084862. In a preferred configuration, the support is mounted on the external surface of a drum, e.g. the plate cylinder of a printing press, and the spray head translates along the support in the axial direction while the drum is rotating in the angular direction.

The exposure step (c)

The imaging materials described herein are suitable for off-press and on-press exposure. They can be exposed to heat or to infrared light, e.g. by means of a thermal head, LEDs or an infrared laser. Preferably, a laser emitting near infrared light having a wavelength in the range from about 700 to about 1500 nm is used, e.g. a semiconductor laser diode, a Nd:YAG or a Nd:YLF laser. The required laser power depends on the sensitivity of the image-recording layer, the pixel dwell time of the laser beam, which is determined by the spot diameter (typical value of modern plate-setters at 1/e² of maximum intensity: 10-25 μm), the scan speed and the resolution of the exposure apparatus (i.e. the number of addressable pixels per unit of linear distance, often expressed in dots per inch or dpi; typical value: 1000-4000 dpi). Two types of laser-exposure apparatuses are commonly used: internal (ITD) and external drum (XTD) plate-setters. ITD plate-setters for thermal plates are typically characterized by a very high scan speed up to 500 m/sec and may require a laser power of several Watts. XTD plate-setters for thermal plates having a typical laser power from about 200 mW to about 1 W operate at a lower scan speed, e.g. from 0.1 to 10 m/sec.

Due to the heat generated during the exposure step, the hydrophobic thermoplastic polymer particles fuse or coagulate so as to form a hydrophobic phase which corresponds to the printing areas of the printing master. Coagulation may result from heat-induced coalescence, softening or melting of the thermoplastic polymer particles. There is no specific upper limit to the coagulation temperature of the thermoplastic hydrophobic polymer particles, however the temperature should be sufficiently below the decomposition temperature of the polymer particles. Preferably the coagulation temperature is at least 10° C. below the temperature at which the decomposition of the polymer particles occurs. The coagulation temperature is preferably higher than 50° C., more preferably above 100° C.

The processing step (d)

During the processing step, the image recording layer is removed from the hydrophilic surface at unexposed areas without substantially removing the image recording layer at exposed areas, i.e. without affecting the exposed areas to an extent that renders the ink-acceptance of the exposed areas insufficient. This can e.g. be achieved by supplying to the image recording layer a processing liquid selected from the group consisting of water, an aqueous liquid, a gum solution, ink, fountain or single-fluid ink. As a result of the processing, a printing master is obtained which contains a lithographic image consisting of hydrophobic (printing) areas and hydrophilic (non-printing) areas. The processing liquid can be supplied to the imaging material e.g. by using a pad that is impregnated with the processing liquid, by pouring, dipping, coating either by hand or in an automatic processing apparatus. In addition, the supply of the processing liquid may be combined with mechanical rubbing, e.g. by a rotating brush. Jetting or spraying the processing liquid is also a suitable method, e.g. by means of the apparatus described in EP-A no. 01000248 filed on Jun. 21, 2001.

The processing step can be carried out on-press by supplying at least one of the mentioned liquids to the imaging material while it is mounted on a cylinder of the printing press, preferably by supplying ink and/or a fountain liquid during the start of the printing press. In that embodiment, step (d) can be regarded as the start of the printing step (e). During such a ‘hidden processing’ step, the unexposed areas are removed from the support by the interaction with the ink and/or fountain. In a preferred embodiment, the dampener rollers that supply dampening liquid are dropped on the imaging material and subsequent thereto the ink rollers are dropped. Generally, after about 10 revolutions of the print cylinder the first clear and useful prints are obtained. According to an alternative method for processing such materials, the ink rollers and dampener rollers may be dropped simultaneously or the ink rollers may be dropped first. Suitable dampening liquids that can be used in connection with such materials are aqueous liquids generally having an acidic pH and comprising an alcohol such as isopropanol.

On-press processing can be used in combination with an on-press exposure step or the imaging material can be exposed with an off-press plate setter, then mounted on the press and processed by starting the press and feeding ink and/or fountain to the imaging material.

Another development method, also suitable for on-press development, especially in driographic presses which do not comprise a dampening system, is performed by supplying single-fluid ink. Single-fluid inks which are suitable for use in the method of the present invention have been described in U.S. Pat. No. 4,045,232 and U.S. Pat. No. 4,981,517. A suitable single-fluid ink comprises an ink phase, also called the hydrophobic or oleophilic phase, and a polyol phase as described in WO 00/32705. More information on the development with single-fluid ink can be found in EP-A no. 01000633, filed on Nov. 15, 2001.

When exposed with an off-press plate-setter, the imaging material can also be processed by supplying plain water, an aqueous is liquid or a gum solution. A gum solution is typically an aqueous liquid which comprises one or more surface protective compounds that are capable of protecting the lithographic image of a printing plate against contamination or damaging. Suitable examples of such compounds are film-forming hydrophilic polymers or surfactants. More information on the development with a gum solution can be found in EP-A no. 02100226, filed on Mar. 6, 2002.

After development, the plate can be dried and baked. The plate can be dried before baking or is dried during the baking process itself. The baking process can proceed at a temperature above the coagulation temperature of the thermoplastic polymer particles, e.g. between 100° C. and 230° C. for a period of 5 to 40 minutes. For example the exposed and developed plates can be baked at a temperature of 230° C. for 5 minutes, at a temperature of 150° C. for 10 minutes or at a temperature of 120° C. for 30 minutes. A preferred baking temperature is above 60° C. Baking can be done in conventional hot air ovens, by inductive heating or by irradiation with lamps emitting in the infrared or ultraviolet spectrum. In a preferred embodiment, the imaging material is processed off-press by applying a baking gum and then baked in an oven or with infrared lamps which may be integrated in the processing apparatus. Alternatively, the baking can also be done while the plate is mounted in a printing press.

The cleaning step (f)

During the cleaning step, the lithographic image is erased by removing the ink-accepting areas from the support. The image erasing step preferably also removes the ink still present on the lithographic image of the previous press run. The cleaning step is preferably characterized by a low risk of deteriorating the lithographic surface of the support, yet also by an effective removal of the ink-accepting areas, which may be a difficult compromise to achieve. The cleaning can be done by supplying a cleaning liquid to the image, e.g. by immersing the printing master in a dip-tank containing the cleaning liquid. The cleaning may also be done scan-wise, e.g. by using a cleaning head comprising a nozzle for jetting or spraying a cleaning liquid onto the image. In the latter embodiment, the same spray or jet head can be used for the cleaning step as the one used in the coating step. Cleaning can also be achieved by dry methods, e.g. by using a laser for ablating the printing areas as described in EP-A no. 1000015, filed on Feb. 14, 2001, or by using an (atmospheric) plasma as described in EP-A 1080942.

The above cleaning methods can be combined with means for ultrasound treatment or mechanical cleaning means. Suitable mechanical means for cleaning the support are e.g. means for scraping the support, means for rubbing the support, e.g. a rotating brush, a cloth or another absorbing medium, which may be moistened with a cleaning liquid. Alternative mechanical cleaning methods involve jetting air, water or dry ice pellets which vaporize during or immediately after the cleaning step. In a preferred embodiment, first a cleaning liquid is supplied to the printing master, e.g. by spraying, and after a short period during which the cleaning liquid is allowed to interact with the lithographic image, a water jet is used for removing the image from the support.

A preferred cleaning liquid should be sufficiently effective, e.g. should be able to avoid the appearance of any ghost image after a plurality of print cycles. Other preferred characteristics of the cleaning liquid are a low volatile organic content to avoid environmental contamination and inertness towards the hardware of the cleaning apparatus, e.g. it is preferably a liquid which does not affect rubber, seals or other materials used in the cleaning apparatus. Suitable cleaning liquid compositions which comply with the above requirements have been disclosed in EP-As 1118470, 1118471, 1118472 and 1118474.

A suitable cleaning liquid is an emulsion of an organic liquid in an aqueous liquid. The preparation of this emulsion is preferably carried out with an off-press apparatus, which may comprise means for mixing an organic liquid with an aqueous liquid so as to form said emulsion, e.g. by stirring a mixture of a cyclic organic compound containing at least one double bond, an alcohol, water and an emulsifying agent. Preferably, the method of the present invention also comprises a step for separating the emulsion (after use) into an organic phase and an aqueous phase, e.g. by heating the emulsion to induce phase-separation. The recycled water thus obtained can be used for preparing fresh emulsion or for rinsing the support after cleaning or prior to recoating.

### EXAMPLES

### Preparation of Lithographic Supports 1-5

A continuous web of aluminum having a thickness of 0.30 mm and a width of 500 mm was degreased by immersing the web in an aqueous solution containing 10 g/l of sodium hydroxide at 39° C. for 35 seconds and then rinsing with demineralized water for 30 seconds. The aluminum web was then electrochemically grained for 30 seconds using an alternating current at a current density as indicated in Table 1 (below) in a mixed acid aqueous solution containing 8.1 g/l of hydrochloric acid and 21.7 g/l of acetic acid at a temperature of 30° C. After rinsing with demineralized water for 30 seconds, the aluminum web was etched to remove smut with an aqueous solution containing 128 g/l of phosphoric acid at 43° C. for 35 seconds and then rinsed with demineralized water for 30 seconds. The aluminum web was subsequently subjected to anodic oxidation for 30 seconds in an aqueous solution containing 154 g/l of sulfuric acid at a temperature of 50° C., using a DC voltage at a current density as indicated in Table 1 below, then washed with demineralized water for 30 seconds and post-treated for 15 seconds with a solution containing 2.45 g/l of polyvinylphosphonic acid at 53° C., rinsed with demineralized water for 30 seconds and dried.

### Preparation of Imaging Materials 1-5

A 2.61 wt. % coating solution in water was prepared by mixing the following ingredients:

a latex copolymer of styrene and acrylonitrile (weight ratio 60/40) having an average particle size of 65 nm, stabilized with an anionic wetting agent;

the infrared absorbing dye IR-1;

polyacrylic acid (Glascol D15 from Allied Colloids, molecular weight 2.7×10⁷ g/mole).

Imaging materials 1-5 were prepared by spraying, as described below, the above coating solution onto the supports 1-5 respectively. After drying, the image-recording layer consisted of 600 mg/m² of the latex, 60 mg/m² of the dye IR-1 and 120 mg/m² of the polyacrylic acid.

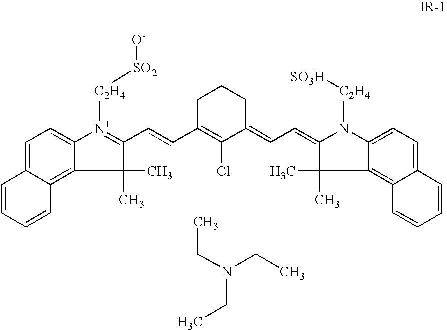

The spraying was carried out by mounting the lithographic support on the external surface of a drum. The coating solution was then applied on the support by a spray nozzle moving in the axial direction of the cylinder at a speed of 1.5 m/min while the drum was rotating at a line speed of 164 m/min. The spray nozzle was of the type SUV76, an air assisted spray nozzle, commercially available at Spraying Systems Belgium, Brussels, and mounted at a distance of 40 mm between the nozzle and the support. The flow rate of the spray solution was set to 7 ml/min. During the spray process an air pressure of 90 psi was used on the spray head. The coating was dried at an air temperature of 70° C. during the spraying process.

### Exposure and Processing

The imaging materials thus obtained were exposed with a Creo Trendsetter (plate-setter available from Creo, Burnaby, Canada), operating at 330 mJ/cm² and 150 rpm. After imaging, the plates were mounted on a MO printing press (available from Heidelberger Druckmaschinen AG), and a print job was started using K+E800 ink and 4% Combifix XL with 10% isopropanol as a fountain liquid. The imaging materials were on-press processed by the ink and fountain supplied to the plate during the start of the printing press. After twenty revolutions of the press, printing masters 1-5 were thereby obtained, producing excellent printed copies of the lithographic image.

### Evaluation of Run Length

The press run, that was started in the previous step, was continued. The run length was evaluated by determining the number of copies printed when the degradation, due to image wear, of a 60% screen of a high quality image (200 lpi) exceeds 5%. The data for Example 1, 2 and 5 in Table 1 (below) demonstrate that for a given anodic weight (4.8 g/m²), the run length significantly improves by reducing Ra. For a given Ra value (Examples 2-4: 0.28 μm), a further improvement is achieved by increasing the anodic weight. Plate 5 still showed no image wear after 90 000 copies when the press run was stopped.

TABLE 1
current densities for graining (GR) and
anodizing (AN), surface roughness Ra and the anoclic
weight (AW) of lithographic supports 1-5 and the run
length achieved with the printing masters obtained
therewith.

| | current | Ra | current | AW | Run |
|---|---|---|---|---|---|
| Example no. | GR (A/m²) | (μm) | AN (A/m²) | (g/m²) | length |
| 1 (comp.) | 2740 | 0.53 | 2350 | 4.8 | 11 000 |
| 2 (Inv.) | 1300 | 0.28 | 2350 | 4.8 | 55 000 |
| 3 (Inv.) | 1300 | 0.28 | 1750 | 3.5 | 50 000 |
| 4 (Inv.) | 1300 | 0.28 | 2900 | 6.3 | 70 000 |
| 5 (Inv.) | 1000 | 0.21 | 2350 | 4.8 | >90 000 |

### Recycling the Support

A cleaning liquid was prepared by mixing 75 g of methylglycol with 5 g of demineralized water. While stirring, 20 ml of a 10 wt. % aqueous solution of NH₄F and then 1 ml of a 30 wt. % aqueous solution of HCl were added.

After the run length test, the lithographic supports 1-5 were recycled by spraying 10 ml/m² of the cleaning liquid on the lithographic image of the plates, using a manual pressure sprayer from Premal Sprayer Division of Precision Valve Corporation, New York. The cleaner was allowed to interact with the image during 30 seconds and then the image was erased by means of a conventional high pressure wasser operating at a flow rate of 5 litre/m² of water. Finally, the recycled supports were treated with pressurised air at room temperature until the surface was dry.

The supports thus obtained were reused in five more cycles of the steps of coating, exposing, processing, printing and cleaning, which were all identical to the above procedure. After each cycle, the plate cleanliness, coating quality and printing quality (staining, presence of ghost images) were evaluated visually. Each of the above press runs produced excellent results for all those criteria.

1. A lithographic printing method comprising the steps of:
(a) providing a lithographic support having a hydrophilic surface;
(b) applying on the hydrophilic surface an image recording layer which comprises hydrophobic thermoplastic polymer particles;
(c) image-wise exposing the image recording layer to heat or light thereby inducing coalescence of the hydrophobic thermoplastic polymer particles at exposed areas;
(d) developing the image recording layer, thereby obtaining a printing master containing a lithographic image;
(e) producing a plurality of printed copies by supplying ink to the lithographic image of the printing master and transferring the ink from the printing master to paper;
(f) recycling the lithographic support by erasing the lithographic image;
(g) using the recycled lithographic support in a next cycle comprising steps (a) to (e) and optionally also (f) and (g);
characterized in that the lithographic support is a grained and anodized aluminum support of which the hydrophilic surface has a surface roughness, expressed as arithmetical mean center-line roughness Ra, which is less than 0.45 μm and which comprises more than 3.5 g/m² of aluminum oxide at the surface.

2. A method according to claim 1 wherein at least 30,000 printed copies are produced during step (e).

3. A method according to claim 1 wherein the hydrophobic thermoplastic polymer particles comprise a homopolymer or a copolymer of (meth)acrylonitrile and/or styrene.

4. A method according to claim 1 wherein the hydrophobic thermoplastic polymer particles comprise a copolymer of (meth)acrylonitrile and styrene, and wherein the image recording layer further comprises a hydrophilic binder and an infrared light absorbing dye.

5. A method according to claim 1 wherein the steps (b)-(f) are all carried out while the lithographic support is mounted on a cylinder of a rotary printing press.

6. A method according to claim 1 comprising the steps of:
(i) carrying out step (b) with an off-press apparatus;
(ii) carrying out steps (c)-(e) while the lithographic support is mounted on a cylinder of a rotary printing press;
(iii) carrying out step (f) with an off-press apparatus or while the lithographic support is mounted on a cylinder of a rotary printing press.

7. A method according to claim 1 comprising the steps of:
(i) carrying out steps (b)-(c) with an off-press apparatus;
(ii) carrying out steps (d)-(e) while the lithographic support is mounted on a cylinder of a rotary printing press;
(iii) carrying out step (f) with an off-press apparatus or while the lithographic support is mounted on a cylinder of a rotary printing press.

8. A method according to claim 6 wherein step (d) is carried out by supplying ink and/or fountain liquid to the image recording layer.

9. A method according to claim 1 comprising the steps of:
(i) carrying out steps (b)-(d) with an off-press apparatus;
(ii) carrying out step (e) while the lithographic support is mounted on a cylinder of a rotary printing press;
(iii) carrying out step (f) with an off-press apparatus or while the lithographic support is mounted on a cylinder of a rotary printing press.

10. A method according to claim 9 wherein a gum solution is used in step (d) as a processing liquid.

11. A method according to claim 10 wherein the gum solution is a baking gum solution and wherein between steps (d) and (e) the printing master is baked by heating with hot air or by irradiation with infrared lamps and wherein the number of printed copies produced during step (e) is higher then 100 000.

12. A method according to claim 1 wherein during step (b) the image recording layer is applied to the hydrophilic surface of the lithographic support by means of a spray nozzle or an ink-jet nozzle.

13. A method according to claim 1 wherein during step (d) a processing liquid is applied to the image recording layer by means of a spray nozzle or an ink-jet nozzle.

14. A method according to claim 1 wherein during step (f) a cleaning liquid is applied to the lithographic image by means of a spray nozzle or an ink-jet nozzle.
